(19) United States
(12) Patent Application Publication
(10) Pub. No.: US 2025/0183186 A1
(43) Pub. Date: Jun. 5, 2025

(54) SEMICONDUCTOR PACKAGE

(71) Applicant: SAMSUNG ELECTRONICS CO., LTD., SUWON-SI (KR)

(72) Inventors: Sungoh Ahn, Suwon-si (KR); Sangsub Song, Suwon-si (KR); Seokbeom Yong, Suwon-si (KR)

(21) Appl. No.: 18/802,083

(22) Filed: Aug. 13, 2024

(30) Foreign Application Priority Data
Dec. 5, 2023 (KR) 10-2023-0174834

(51) Int. Cl. H01L 23/538; H01L 23/00; H01L 23/498; H01L 23/64; H01L 25/065; H05K 1/11; H05K 1/18

(52) U.S. Cl. CPC H01L 23/5386; H01L 23/49833; H01L 23/5385; H01L 23/642; H01L 24/16; H05K 1/181; H01L 24/32; H01L 24/73; H01L 25/0655; H01L 2224/16225; H01L 2224/32225; H01L 2224/73204; H01L 2924/1431; H05K 1/111; H05K 2201/09218; H05K 2201/09372; H05K 2201/09654; H05K 2201/10378; H05K 2201/10734

(57) ABSTRACT

A semiconductor package includes a package substrate including a first voltage substrate wire, an interposer substrate provided on the package substrate and including a first voltage interposer wire, a first semiconductor chip mounted on a top surface of the interposer substrate, and a voltage control chip provided on the top surface of the interposer substrate and laterally spaced apart from the first semiconductor chip, wherein the first semiconductor chip is electrically connected to the voltage control chip through the first voltage substrate wire, and wherein the first semiconductor chip is electrically connected to the voltage control chip through the first voltage interposer wire.

### CROSS-REFERENCE TO RELATED APPLICATION

This application is based on and claims priority under 35 U.S.C. § 119 to Korean Patent Application No. 10-2023-0174834, filed on Dec. 5, 2023, in the Korean Intellectual Property Office, the contents of which are incorporated by reference herein in their entirety.

### TECHNICAL FIELD

The present disclosure relates to a semiconductor package, and more particularly, to a semiconductor package including an interposer substrate.

### BACKGROUND

In the field of semiconductor packaging, optimizing electrical characteristics is paramount for ensuring the reliability and performance of electronic devices. As electronic components continue to shrink in size and increase in complexity, semiconductor packages play a pivotal role in protecting and interconnecting these components while maintaining optimal electrical performance. A semiconductor package may be an integrated circuit chip implemented in a form suitable for use in a variety of electronic products.

In some cases, a semiconductor package may include a semiconductor chip mounted on a printed circuit board. For example, the semiconductor chip may be electrically connected to a printed circuit board using bonding wires or bumps. However, challenges arise in achieving the desired electrical characteristics (e.g., in terms of impedance matching, signal integrity, etc.) in case of high-speed and high-frequency applications. In some cases, currently used semiconductor packages may not be able to meet the stringent requirements, leading to issues such as signal degradation, electromagnetic interference, etc., which can compromise the functionality and longevity of electronic systems. Therefore, there is a need in the art for systems and methods that can improve the electrical characteristics of the semiconductor packages.

### SUMMARY

The present disclosure provides a semiconductor package with improved electrical characteristics. Embodiments of the present disclosure include a semiconductor package comprising a package substrate and an interposer substrate. For example, the package substrate and the interposer substrate may include a voltage substrate wire and a voltage interposer wire, respectively. In some cases, a voltage may be output from a voltage control chip and may be supplied to a semiconductor chip via the voltage interposer wire and the voltage substrate wire.

According to an aspect of the present disclosure, a semiconductor package includes a package substrate including a first voltage substrate wire, an interposer substrate disposed on the package substrate and including a first voltage interposer wire, a first semiconductor chip mounted on a top surface of the interposer substrate, and a voltage control chip disposed on the top surface of the interposer substrate and laterally spaced apart from the first semiconductor chip, wherein the first semiconductor chip is electrically connected to the voltage control chip through the first voltage substrate wire, and wherein the first semiconductor chip is electrically connected to the voltage control chip through the first voltage interposer wire.

According to another aspect of the present disclosure, a semiconductor package includes a package substrate including a first voltage substrate wire, an interposer substrate disposed on the package substrate and including a first voltage interposer wire and a first capacitor, a first semiconductor chip mounted on a top surface of the interposer substrate, and a first voltage control chip disposed on the top surface of the interposer substrate and laterally spaced apart from the first semiconductor chip, wherein the first capacitor includes a first terminal connected to the first semiconductor chip, and a second terminal electrically connected to the first voltage substrate wire, and wherein a thickness of the first voltage substrate wire is greater than a thickness of the first voltage interposer wire.

According to another aspect of the present disclosure, a semiconductor package includes a package substrate including a first voltage substrate wire, a voltage supply substrate wire, and a signal wire, solder ball terminals disposed on a bottom surface of the package substrate, an interposer substrate disposed on a top surface of the package substrate and including a first voltage interposer wire, a voltage supply interposer wire, a signal interposer wire, and a first capacitor, interposer solder balls disposed between the package substrate and the interposer substrate, a first semiconductor chip disposed on a top surface of the interposer substrate, first bumps disposed between the interposer substrate and the first semiconductor chip and connected to the interposer substrate and the first semiconductor chip, a voltage control chip disposed on the top surface of the interposer substrate and laterally spaced apart from the first semiconductor chip, and a molding layer provided on the top surface of the interposer substrate and covering the first semiconductor chip and the voltage control chip, wherein the first capacitor includes a first terminal connected to the first voltage substrate wire and the first voltage interposer wire, and a second terminal electrically connected to the first semiconductor chip, wherein the solder ball terminals include a voltage solder ball terminal and a signal solder ball terminal, the voltage solder ball terminal is electrically connected to the first voltage control chip through the voltage supply substrate wire and the voltage supply interposer wire, the first voltage substrate wire is insulated from the voltage supply substrate wire, the first voltage interposer wire is insulated from the voltage supply interposer wire, and a thickness of the first voltage substrate wire is greater than a thickness of the first voltage interposer wire.

According to another aspect of the present disclosure, there is provided a semiconductor package including a package substrate, an interposer substrate disposed on the package substrate, a first semiconductor chip mounted on a top surface of the interposer substrate, a voltage control chip disposed on the top surface of the interposer substrate and laterally spaced apart from the first semiconductor chip, a first voltage substrate wire located within the package substrate, wherein the first voltage substrate wire forms a first electrical connection between the first semiconductor chip and the voltage control chip, and a first voltage interposer wire located within the interposer substrate, wherein the first voltage interposer wire forms a second electrical connection between the first semiconductor chip and the voltage control chip, and wherein the first electrical connection and the second electrical connection comprise parallel connections between the first semiconductor chip and the voltage control chip.

### BRIEF DESCRIPTION OF THE DRAWINGS

Embodiments of the present disclosure may be understood from the following detailed description taken in conjunction with the accompanying drawings:

FIG. 1A is a plan view of a semiconductor package according to an embodiment;

FIG. 1B is a cross-sectional view taken along a line I-I′ of FIG. 1A;

FIG. 1C is an enlarged view of a region A of FIG. 1B;

FIG. 1D is a cross-sectional view taken along a line II-II′ of FIG. 1A;

FIG. 1E is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip;

FIG. 1F is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip;

FIG. 1G is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip;

FIG. 1H is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip;

FIG. 2A is a cross-sectional view of a semiconductor package according to an embodiment;

FIG. 2B is a cross-sectional view of a semiconductor package according to an embodiment;

FIG. 3A is a cross-sectional view of a semiconductor package according to an embodiment;

FIG. 3B is an enlarged view of a region B of FIG. 3A;

FIG. 3C is a cross-sectional view of a semiconductor package according to an embodiment;

FIG. 4A is a cross-sectional view of a semiconductor package according to an embodiment;

FIG. 4B is a cross-sectional view of a semiconductor package according to an embodiment;

FIG. 5A is a cross-sectional view of a semiconductor package according to an embodiment;

FIG. 5B is a cross-sectional view of a semiconductor package according to an embodiment;

FIG. 6A is a plan view of a semiconductor package according to an embodiment;

FIG. 6B is a cross-sectional view of the semiconductor package of FIG. 6A taken along a line I-I′; and

FIG. 6C is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip of the semiconductor package of FIG. 6A.

### DETAILED DESCRIPTION OF THE EMBODIMENTS

The present disclosure provides a semiconductor package with improved electrical characteristics. Embodiments of the present disclosure include a semiconductor package comprising a package substrate and an interposer substrate. For example, the package substrate and the interposer substrate may include a voltage substrate wire and a voltage interposer wire, respectively. In some cases, a voltage may be output from a voltage control chip and may be supplied to a semiconductor chip via the voltage interposer wire and the voltage substrate wire.

Existing systems include a voltage output from a voltage control chip that may be supplied to a semiconductor chip. In some cases, the voltage control chip and the semiconductor chip may be arranged on a substrate and may be connected to each other. However, such connections between the semiconductor chip and the voltage control chip may result in a high voltage drop. Additionally, such systems may exhibit high direct current resistance characteristics. As a result, the electrical characteristics of the semiconductor package may be reduced.

By contrast, embodiments of the present disclosure include a semiconductor package, where a voltage output from a voltage control chip may be supplied to the semiconductor chip through a voltage interposer wire and a voltage substrate wire. In some cases, a thickness of the voltage substrate wire may be greater than a thickness of the voltage interposer wire and a resistance of the voltage substrate interposer wire may be smaller than a resistance of the voltage interposer wire. For example, a voltage may be applied to a voltage solder ball terminal from an external device. In some cases, the voltage may be applied to the voltage control chip via the voltage substrate wire and the voltage interposer wire. A voltage controller of the voltage control chip may modify the voltage to generate a modified voltage that may be transmitted to an inductor.

In some cases, the modified voltage may be transmitted to the interposer substrate via the inductor. As such, the modified voltage may be transmitted to the voltage substrate wire through a conductive bump. Additionally, in some cases, a part of the modified voltage may be transmitted to a capacitor disposed in the interposer substrate via the voltage interposer wire. In some cases, since the modified voltage may be supplied from the voltage control chip to the capacitor via the interposer wire, a length of the voltage supply path may be reduced.

According to an embodiment, the semiconductor chip may include a first semiconductor chip and a second semiconductor chip. In some cases, the capacitor may be disposed to vertically overlap the first semiconductor chip. In some cases, the capacitor may be disposed to vertically overlap the second semiconductor chip. By providing a capacitor such that the capacitor overlaps the semiconductor chip, a length of a voltage supply path between the capacitor and the semiconductor chip may be reduced. Therefore, the semiconductor package may exhibit improved voltage characteristics.

Accordingly, by providing a voltage output from a voltage control chip to a semiconductor chip through a voltage interposer wire and a voltage substrate wire, wherein a thickness of the voltage substrate wire may be greater than a thickness of the voltage substrate wire, embodiments of the present disclosure are able to prevent a voltage loss during a voltage supply process. Additionally, in some cases, a voltage drop phenomenon may be reduced. Therefore, the semiconductor package may exhibit improved electrical properties due to enhanced power integrity characteristics between the voltage control chip and the first semiconductor chip.

The present disclosure may be modified in multiple alternate forms, and thus specific embodiments will be exemplified in the drawings and described in detail. In the present specification, when a component (or a region, a layer, a portion, etc.) is referred to as being “on,” “connected to,” or “coupled to” another component, it means that the component may be directly disposed on/connected to/coupled to the other component, or that a third component may be disposed therebetween.

Like reference numerals may refer to like components throughout the specification and the drawings. It is noted that while the drawings are intended to illustrate actual relative dimensions of a particular embodiment of the specification, the present disclosure is not necessarily limited to the embodiments shown. The term “and/or” includes all combinations of one or more of which associated configurations may define.

It will be understood that, although the terms “first,” “second,” etc. may be used herein to describe various components, these components should not necessarily be limited by these terms. These terms are only used to distinguish one component from another. For example, a first component could be termed a second component, and, similarly, a second component could be termed a first component, without departing from the scope of the inventive concept. The terms of a singular form may include plural forms unless the context clearly indicates otherwise.

Additionally, terms such as “below,” “under,” “on,” and “above” may be used to describe the relationship between components illustrated in the figures. The terms are used as a relative concept and are described with reference to the direction indicated in the drawings. It should be understood that the terms “comprise,” “include,” or “have” are intended to specify the presence of stated features, integers, steps, operations, components, parts, or combinations thereof in the disclosure, but do not preclude the presence or addition of one or more other features, integers, steps, operations, components, parts, or combinations thereof.

In the present specification, although terms such as first and second are used to describe various elements or components, it goes without saying that these elements or components are not limited by these terms. These terms are only used to distinguish a single element or component from other elements or components. Therefore, it goes without saying that a first element or component referred to below may be a second element or component within the technical idea of the present invention.

Hereinafter, a system for a semiconductor package of the embodiments of the present disclosure will be described in detail with reference to the accompanying drawings.

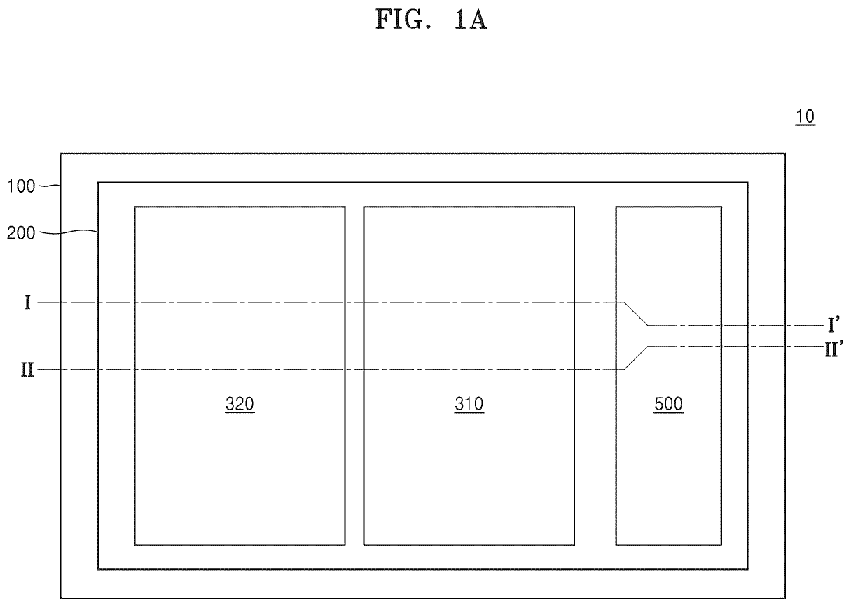

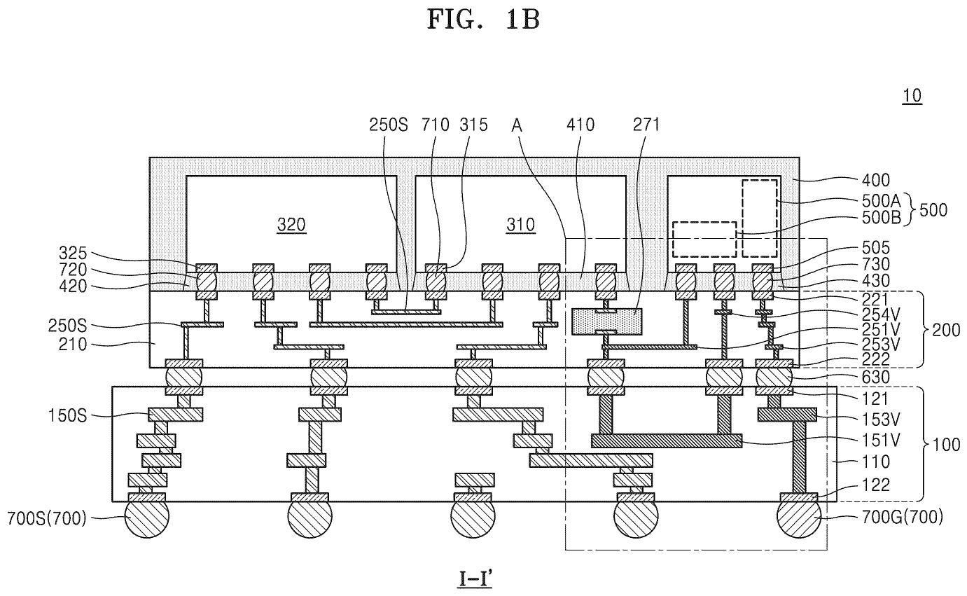

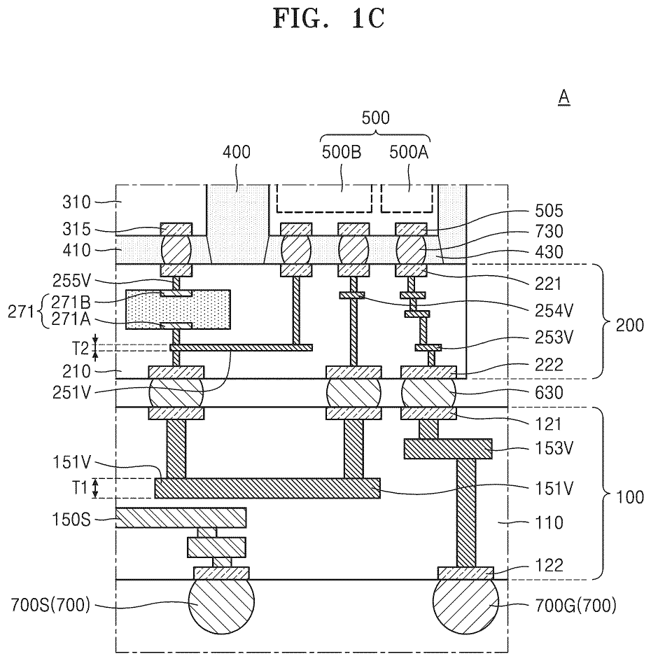

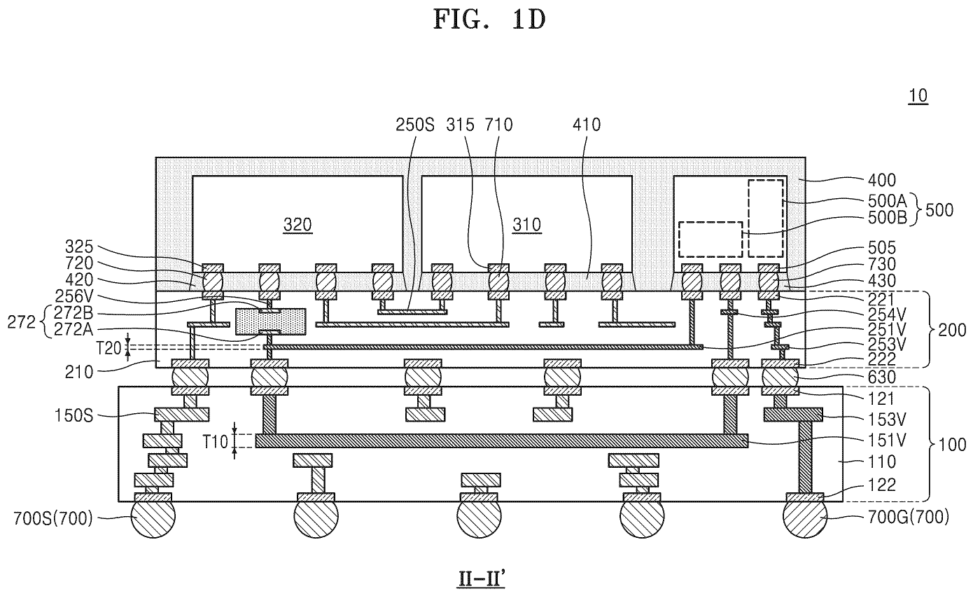

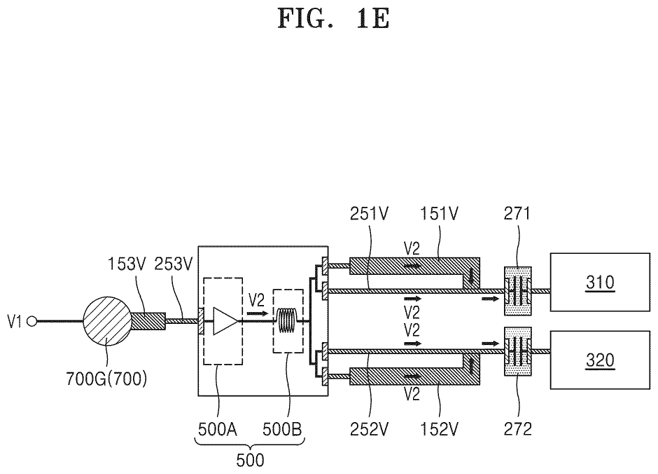

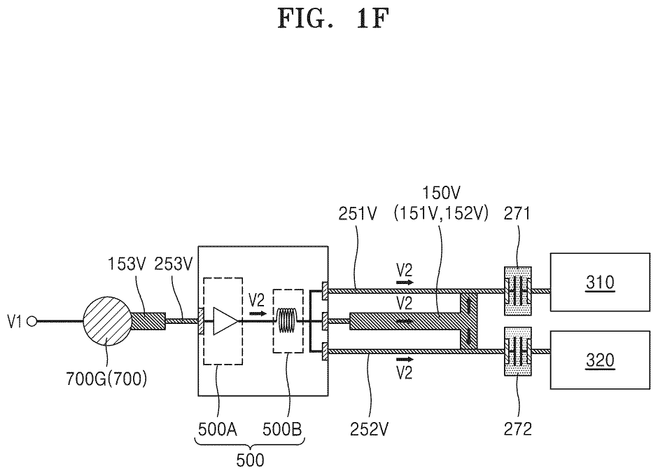

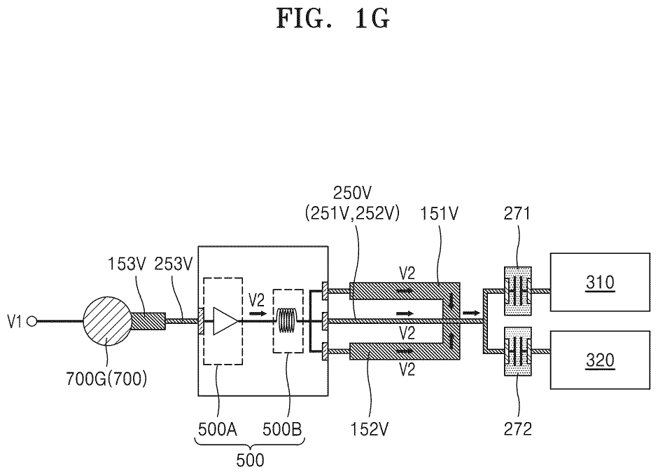

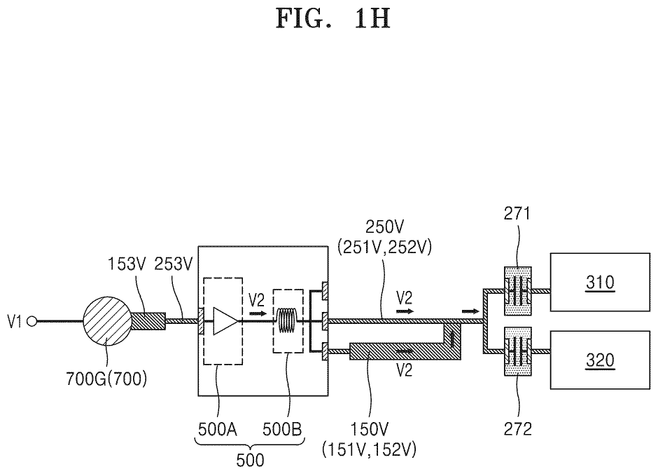

FIG. 1A is a plan view of a semiconductor package according to embodiments. FIG. 1B is a cross-sectional view taken along a line I-I′ of FIG. 1A. FIG. 1C is an enlarged view of a region A of FIG. 1B. FIG. 1D is a cross-sectional view taken along a line II-II′ of FIG. 1A.

Referring to FIGS. 1A to 1D, a semiconductor package 10 may include solder ball terminals 700, a package substrate 100, an interposer substrate 200, a first semiconductor chip 310, a voltage control chip 500, and a molding layer 400. The semiconductor package 10 may further include a second semiconductor chip 320. The semiconductor package 10 may further include interposer solder balls 630.

The package substrate 100 may include a printed circuit board. The package substrate 100 may include a first insulation layer 110, first lower pads 122, substrate wires 150S, 151V, 152V, and 153V, and first upper pads 121. The first insulation layer 110 may include at least one of an organic material such as an insulation resin and an inorganic material such as glass fiber. For example, the first insulation layer 110 may include prepreg. In some cases, the first insulation layer 110 may be a multi-layer. As used herein, provided within the package substrate 100 may mean provided within the first insulation layer 110. The first lower pads 122, the substrate wires 150S, 151V, 152V, and 153V, and the first upper pads 121 may each include a metal material such as copper, aluminum, tungsten, titanium, and/or an alloy thereof.

The first upper pads 121 may be arranged on the top surface of the package substrate 100. The first upper pads 121 may include first upper signal pads and a first upper voltage pad. The first upper voltage pad may be spaced apart and may be insulated from the first upper signal pads.

The first lower pads 122 may be provided on the bottom surface of the package substrate 100. The first lower pads 122 may include first lower signal pads and a first lower voltage pad. In some cases, the first lower voltage pad may be spaced apart and may be electrically isolated from the first lower signal pads.

The solder ball terminals 700 may be provided on the bottom surface of the package substrate 100. For example, the solder ball terminals 700 may be provided on the bottom surfaces of the first lower pads 122 and may be connected to the first lower pads 122. The solder ball terminals 700 may include signal solder ball terminals 700S and voltage solder ball terminals 700G. A voltage solder ball terminal 700G may be spaced apart from the signal solder ball terminals 700S and may be insulated from the signal solder ball terminals 700S. The solder ball terminals 700 may include a solder material. The solder material may include, for example, tin (Sn), silver (Ag), zinc (Zn), and/or alloys thereof. However, embodiments may not be limited thereto.

The substrate wires 150S, 151V, 152V, and 153V may include signal substrate wires 150S, a first voltage substrate wire 151V, a second voltage substrate wire 152V, and a third voltage substrate wire 153V. In some cases, the substrate wires 150S, 151V, 152V, and 153V are provided in the package substrate 100 and may be electrically connected to the first upper pads 121. As used herein, electrically connected to the package substrate 100 may mean electrically connected to at least one of the signal substrate wires 150S, the first voltage substrate wire 151V, the second voltage substrate wire 152V, and the third voltage substrate wire 153V. For example, an electrical connection of two components may include a direct connection of the two components and an indirect connection of the two components through another conductive component.

The number of stacked substrate wires 150S, 151V, 152V, and 153V may be between 1 and 10, but is not limited thereto. The number of the stacked substrate wires 150S, 151V, 152V, and 153V may refer to the number of substrate wires 150S, 151V, 152V, and 153V provided at different levels. In some cases, the level of a certain component may refer to a vertical level of the component. For example, vertical refers to the direction aligned with the vertical axis or perpendicular to the horizon (such as a horizontal axis or a flat surface or a plane). As used herein, the term vertical may mean perpendicular to the top surface of the package substrate 100.

The signal substrate wires 150S may be electrically connected to signal solder balls 700S through some of the first lower pads 122. Signal substrate patterns 150S may be electrically connected to some of the first upper pads 121. The some of the first lower pads 122 may be first lower signal pads. Additionally, the some of the first upper pads 121 may be first upper signal pads. Therefore, the first upper signal pads may be electrically connected to the signal solder balls 700S through the signal substrate wires 150S.

The package substrate 100 may further include first conductive vias. The first conductive vias may be provided between the substrate wires 150S, 151V, 152V, and 153V, between the substrate wires 150S, 151V, 152V, and 153V and the first lower pads 122, or between the substrate wires 150S, 151V, 152V, and 153V and the first upper pads 121. Electrical connection to the substrate wires 150S, 151V, 152V, and 153V may include electrical connection to the substrate wires 150S, 151V, 152V, and 153V through first conductive vias.

First to third voltage substrate wires 151V, 152V, and 153V may be electrically connected to some other of the first upper pads 121. The some other first upper pads 121 may be first upper voltage pads. The first to third voltage substrate wires 151V, 152V, and 153V may be spaced apart and electrically isolated from the signal substrate wires 150S.

The third voltage substrate wire 153V may be electrically connected to the voltage solder ball terminal 700G through any one first lower pad 122. The any one first lower pad 122 may be a first lower voltage pad. The third voltage substrate wire 153V may be a voltage supply wire. A voltage applied to the voltage solder ball terminal 700G may be transmitted to the third voltage substrate wire 153V. The third voltage substrate wire 153V may be electrically connected to any one first upper pad 121. Therefore, the any one first upper pad 121 may be electrically connected to the voltage solder ball terminal 700G through the third voltage substrate wire 153V. Any of the first upper pads 121 may be a first upper voltage pad.

The first voltage substrate wire 151V may be electrically connected to at least two first upper pads 121. The first voltage substrate wire 151V may be a first voltage transmission wire. The at least two first upper pads 121 may be first upper voltage pads. The first voltage substrate wire 151V may be spaced apart and insulated from the solder ball terminals 700 and the first lower pads 122. The first voltage substrate wire 151V may be spaced apart and insulated from the third voltage substrate wire 153V. A thickness (T1 of FIG. 1C) of the first voltage substrate wire 151V may be between 5 μm and 50 μm. The width of the first voltage substrate wire 151V may be between 0.5 mm and 3 mm. As described herein, the width of a wire may be measured in a direction perpendicular to a direction in which the wire extends in a plan view.

As shown in FIG. 1D, the second voltage substrate wire 152V may be electrically connected to at least two first upper pads 121. In some cases, the second voltage substrate wire 152V may be a second voltage transmission wire. The at least two first upper pads 121 may be first upper voltage pads. The second voltage substrate wire 152V may be spaced apart and insulated from the solder ball terminals 700 and the first lower pads 122. The second voltage substrate wire 152V may be spaced apart and insulated from the third voltage substrate wire 153V. A thickness T10 of the second voltage substrate wire 152V may be between 5 μm and 50 μm. The thickness T10 of the second voltage substrate wire 152V may be substantially identical to the thickness (T1 of FIG. 1C) of the first voltage substrate wire 151V, but is not limited thereto. The width of the second voltage substrate wire 152V may be between 0.5 mm and 3 mm.

According to an embodiment, the second voltage substrate wire 152V may be spaced apart from the first voltage substrate wire (151V of FIG. 1B). The second voltage substrate wire 152V may be electrically isolated from the first voltage substrate wire 151V. According to an embodiment, the second voltage substrate wire 152V may be connected to the first voltage substrate wire 151V. According to an embodiment, the second voltage substrate wire 152V may be integrated with the first voltage substrate wire 151V. Further details regarding the first voltage substrate wire 151V and the second voltage substrate wire 152V have been provided with reference to FIGS. 1E to 1H.

The interposer substrate 200 may be disposed over the package substrate 100. The interposer substrate 200 may include a second insulation layer 210, second lower pads 222, second upper pads 221, interposer wires 250S, 251V, 252V, 253V, 254V, 255V, and 256V, a first capacitor 271, and a second capacitor 272. In some examples, the second insulation layer 210 may include an insulation polymer or a silicon-based insulation material. In some cases, the second insulation layer 210 may be a multi-layer. As used herein, provided within the interposer substrate 200 may mean being provided within the second insulation layer 210.

The second lower pads 222 may be provided on the bottom surface of the interposer substrate 200. The second lower pads 222 may include second lower signal pads and second lower voltage pads. The second lower voltage pads may be spaced apart and may be electrically isolated from the second lower signal pads. The second lower pads 222 may include a metal material such as copper, aluminum, tungsten, titanium, and/or alloys thereof.

The interposer solder balls 630 are provided between the package substrate 100 and the interposer substrate 200 and may be connected to the first upper pads 121 and the second lower pads 222. Therefore, the interposer substrate 200 may be electrically connected to the package substrate 100 through the interposer solder balls 630. The interposer solder balls 630 may include a solder material. The interposer solder balls 630 may include signal interposer solder balls and voltage interposer solder balls. The signal interposer solder balls may be electrically connected to the signal solder ball terminals 700S through the second lower voltage pads and the signal substrate wires 150S. The pitch of the signal interposer solder balls may be smaller than the pitch of the signal solder ball terminals 700S. The voltage interposer solder balls may be insulated from the signal interposer solder balls. The voltage interposer solder balls may be connected to the second lower voltage pads.

The interposer wires 250S, 251V, 252V, 253V, 254V, 255V, and 256V may include signal interposer wires 250S, a first voltage interposer wire 251V, a second voltage interposer wire 252V, a third voltage interposer wire 253V, a fourth voltage interposer wire 254V, a fifth voltage interposer wire 255V, and a sixth voltage interposer wire 256V. As used herein, electrically connected to the interposer substrate 200 may mean electrically connected to the signal interposer wires 250S and at least one of first to sixth voltage interposer wires 251V, 252V, 253V, 254V, 255V, and 256V. The interposer wires 250S, 251V, 252V, 253V, 254V, 255V, and 256V may include a metal material, such as copper, titanium, and/or alloys thereof.

The interposer wires 250S, 251V, 252V, 253V, 254V, 255V, and 256V may be provided in the interposer substrate 200 and may be electrically connected to the second lower pads 222. The number of stacked interposer wires 250S, 251V, 252V, 253V, 254V, 255V, and 256V may refer to the number of the interposer wires 250S, 251V, 252V, 253V, 254V, 255V, and 256V provided at different levels. The number of the stacked interposer wires 250S, 251V, 252V, 253V, 254V, 255V, and 256V may be smaller than the number of the stacked substrate wires 150S, 151V, 152V, and 153V. For example, the number of stacked signal interposer wires 250S may be smaller than the number of stacked signal substrate wires 150S. The number of the stacked interposer wires 250S, 251V, 252V, 253V, 254V, 255V, and 256V may be between 1 to 4, but is not limited thereto.

The signal interposer wires 250S may be electrically connected to the signal substrate wires 150S through some of the second lower pads 222 and some of the interposer solder balls 630. The some of the second lower pads 222 may be second lower signal pads. Additionally, the some of the interposer solder balls 630 may be signal interposer solder balls and may correspond to the some of the second lower pads 222. In some cases, the signal interposer wires 250S may be spaced apart and may be insulated from the first to sixth voltage interposer wires 251V, 252V, 253V, 254V, 255V, and 256V.

The second upper pads 221 may be arranged on the top surface of the interposer substrate 200 and may be electrically connected to the interposer wires 250S, 251V, 252V, 253V, 254V, 255V, and 256V. Therefore, the second upper pads 221 may be electrically connected to the second lower pads 222 through the interposer wires 250S, 251V, 252V, 253V, 254V, 255V, and 256V. The second upper pads 221 may include second upper signal pads and second upper voltage pads. The second upper signal pads may be electrically connected to the signal interposer wires 250S. The second upper voltage pads may be electrically connected to the first to sixth voltage interposer wires 251V, 252V, 253V, 254V, 255V, and 256V. The second upper voltage pads may be spaced apart and may be electrically isolated from the second upper signal pads and the signal interposer wires 250S. In some examples, the second upper pads 221 may include a metal material such as copper, aluminum, tungsten, titanium, and/or alloys thereof.

The interposer substrate 200 may further include second conductive vias. The second conductive vias may be provided between the interposer wires 250S, 251V, 252V, 253V, 254V, 255V, and 256V, between the interposer wires 250S, 251V, 252V, 253V, 254V, 255V, and 256V and the second lower pads 222, or between the interposer wires 250S, 251V, 252V, 253V, 254V, 255V, and 256V and the second upper pads 221. As described, electrical connection to the interposer wires 250S, 251V, 252V, 253V, 254V, 255V, and 256V may include electrical connection to the interposer wires 250S, 251V, 252V, 253V, 254V, 255V, and 256V through the second conductive vias.

The third voltage interposer wire 253V may be electrically connected to the third voltage substrate wire 153V through any one second lower pad 222 and any one interposer solder ball 630. The third voltage interposer wire 253V may be a voltage supply wire. The third voltage interposer wire 253V may be connected to any one second upper pad 221. The second lower voltage pads may include the any one second lower pad 222.

The fourth voltage interposer wire 254V may be electrically connected to at least one of the first voltage substrate wire 151V and the second voltage substrate wire 152V through another second lower pad 222 and the interposer solder ball 630 corresponding to the another second lower pad 222. The fourth voltage interposer wire 254V may be connected to another second upper pad 221. The second lower voltage pads may further include the other second lower pad 222. In some cases, the fourth voltage interposer wire 254V may be spaced apart and may be insulated from the third voltage interposer wire 253V. In some cases, a voltage applied to the fourth voltage interposer wire 254V may be different from a voltage applied to the third voltage interposer wire 253V.

As shown in FIGS. 1B and 1C, the first voltage interposer wire 251V may be electrically connected to at least one second upper pad 221. The first voltage interposer wire 251V may be electrically connected to the voltage control chip 500 through the at least one second upper pad 221 and a conductive bump 730 corresponding to the at least one second upper pad 221. The second lower voltage pads may further include the at least one second upper pad 221. The first voltage interposer wire 251V may be spaced apart and insulated from the third voltage interposer wire 253V. According to an embodiment, the first voltage interposer wire 251V may be spaced apart from the fourth voltage interposer wire 254V, but is not limited thereto. A thickness T2 of the first voltage interposer wire 251V may be between 1 μm and 10 μm. The width of the first voltage interposer wire 251V may be between 0.5 mm and 3 mm.

As shown in FIG. 1D, the second voltage interposer wire 252V may be electrically connected to at least one second upper pad 221. The second voltage interposer wire 252V may be electrically connected to the voltage control chip 500 through the at least one second upper pad 221 and a conductive bump 730 corresponding to the at least one second upper pad 221. The second lower voltage pads may further include the at least one second upper pad 221. The second voltage interposer wire 252V may be spaced apart and may be insulated from the third voltage interposer wire 253V. According to an embodiment, the second voltage interposer wire 252V may be spaced apart from the fourth voltage interposer wire 254V, but is not limited thereto. A thickness T20 of the second voltage interposer wire 252V may be between 1 μm and 10 μm. The thickness T20 of the second voltage interposer wire 252V may be substantially identical to the thickness (T2 of FIG. 1C) of the first voltage interposer wire 251V, but is not limited thereto. The width of the second voltage interposer wire 252V may be between 0.5 mm and 3 mm.

According to an embodiment, the second voltage interposer wire 252V may be spaced apart from the first voltage interposer wire (i.e., first voltage interposer wire 251V described with reference to FIG. 1B). The second voltage interposer wire 252V may be electrically isolated from the first voltage interposer wire 251V. In some cases, the second voltage interposer wire 252V may be connected to the first voltage interposer wire 251V. In some cases, the second voltage interposer wire 252V may be integrated with the first voltage interposer wire 251V.

The first capacitor 271 and the second capacitor 272 may be provided in the interposer substrate 200. In some cases, the second capacitor 272 may be spaced apart from the first capacitor 271. In some examples, the first capacitor 271 and the second capacitor 272 may each include a metal-insulator-metal (MIM) capacitor, an integrated stack capacitor (ISC), or a multilayer ceramic capacitor (MLCC), but is not limited thereto.

As shown in FIG. 1C, the first capacitor 271 may include a first terminal 271A and a second terminal 271B. The first terminal 271A of the first capacitor 271 may be electrically connected to the first voltage interposer wire 251V. In some cases, the first capacitor 271 may include a first electrode, a second electrode, and a dielectric. The dielectric may be provided between the first electrode and the second electrode. The first terminal 271A may be connected to the first electrode, and the second terminal 271B may be connected to the second electrode. The second terminal 271B may be insulated from the first terminal 271A. For example, the first terminal 271A may be formed integrally with the first electrode and the second terminal 271B may be formed integrally with the second electrode. However, embodiments may not be limited thereto.

The fifth voltage interposer wire 255V may be provided between the first capacitor 271 and any one first upper pad 121, and thus the fifth voltage interposer wire 255V may be electrically connected to the first capacitor 271 and the any one first upper pad 121. For example, the second terminal 271B of the first capacitor 271 may be electrically connected to the fifth voltage interposer wire 255V. The fifth voltage interposer wire 255V may be spaced apart and insulated from first to fourth voltage interposer wires 251V, 252V, 253V, and 254V.

As shown in FIG. 1D, the second capacitor 272 may include a first conductive terminal 272A and a second conductive terminal 272B. The first conductive terminal 272A of the second capacitor 272 may be electrically connected to the second voltage interposer wire 252V. In some cases, the second capacitor 272 may include a first electrode portion, a second electrode portion, and a dielectric layer. The dielectric layer may be interposed between the first electrode portion and the second electrode portion. The first conductive terminal 272A may be connected to the first electrode portion and the second conductive terminal 272B may be connected to the second electrode portion. The second conductive terminal 272B may be insulated from the first conductive terminal 272A. For example, the first conductive terminal 272A may be formed integrally with the first electrode portion and the second conductive terminal 272B may be formed integrally with the second electrode portion. However, embodiments may not be limited thereto.

The sixth voltage interposer wire 256V may be provided between the second capacitor 272 and another first upper pad 121. Thus, the sixth voltage interposer wire 256V may be electrically connected to the second capacitor 272 and the other first upper pad 121. For example, the second conductive terminal 272B of the second capacitor 272 may be electrically connected to the sixth voltage interposer wire 256V. In some cases, the sixth voltage interposer wire 256V may be spaced apart and may be insulated from first to fifth voltage interposer wires 251V, 252V, 253V, 254V, and 255V.

The first semiconductor chip 310 may be disposed on the top surface of the interposer substrate 200. For example, the first semiconductor chip 310 may be a logic chip. In some examples, the first semiconductor chip 310 may include a buffer chip or a memory chip. The first semiconductor chip 310 may include first chip pads 315 on the bottom surface of the first semiconductor chip 310. In some examples, the first chip pads 315 may include a metal material such as aluminum. However, embodiments may not be limited thereto.

First bumps 710 may be provided between the interposer substrate 200 and the first semiconductor chip 310. In some cases, first bumps 710 may be connected to the first chip pads 315 and the second upper pads 221 corresponding to the first chip pads 315. Therefore, the first semiconductor chip 310 may be electrically connected to the interposer substrate 200 through the first bumps 710. The first semiconductor chip 310 may be electrically connected to the first capacitor 271 through any one first bump 710 and the fifth voltage interposer wire 255V. The first bumps 710 may include first solder balls. The first solder balls may include a solder material. In some cases, the first bumps 710 may further include first pillars. In some cases, the first pillars may be provided between the first chip pads 315 and the first solder balls and may include copper. In some cases, the pitch of the first bumps 710 may be smaller than the pitch of the signal interposer solder balls from among the interposer solder balls 630.

The second semiconductor chip 320 may be disposed on the top surface of the interposer substrate 200 and may be laterally spaced apart from the first semiconductor chip 310. For example, the second semiconductor chip 320 may be disposed between the first semiconductor chip 310 and a first side of the interposer substrate 200 in a plan view. As used herein, any two components laterally spaced apart from each other may mean that the two components are horizontally spaced from each other. For example, as used herein, the term “horizontal” may mean parallel to the top surface of the package substrate 100. The second semiconductor chip 320 may be, for example, a logic chip. In some examples, the second semiconductor chip 320 may include a buffer chip or a memory chip. The second semiconductor chip 320 may include second chip pads 325 on the bottom surface of the second semiconductor chip 320. For example, the second chip pads 325 may include a metal material such as aluminum. The pitch of second bumps 720 may be smaller than the pitch of the signal interposer solder balls from among the interposer solder balls 630.

The second bumps 720 may be provided between the interposer substrate 200 and the second semiconductor chip 320 and may be connected to the second chip pads 325 and the second upper pads 221 corresponding to the second chip pads 325. Therefore, the second semiconductor chip 320 may be electrically connected to the interposer substrate 200 through the second bumps 720. The second semiconductor chip 320 may be electrically connected to the second capacitor 272 through any one second bump 720 and the sixth voltage interposer wire 256V. The second bumps 720 may include second solder balls. The second solder balls may include a solder material. In some cases, the second bumps 720 may further include second pillars. In some cases, the second pillars may be provided between the second chip pads 325 and the second solder balls and may include copper.

The voltage control chip 500 may be disposed on the top surface of the interposer substrate 200 and may be laterally spaced apart from the first semiconductor chip 310 and the second semiconductor chip 320. For example, the voltage control chip 500 may be disposed between the second semiconductor chip 320 and a second side of the interposer substrate 200 in a plan view. The second side of the interposer substrate 200 may be opposite to the first side of the interposer substrate 200. The voltage control chip 500 may include third chip pads 505 on the bottom surface of the voltage control chip 500. The third chip pads 505 may include a metal material such as aluminum. The voltage control chip 500 may include a voltage controller 500A and an inductor 500B. The voltage controller 500A may be electrically connected to the inductor 500B.

Conductive bumps 730 may be provided between the interposer substrate 200 and the voltage control chip 500 and may be connected to the third chip pads 505 and the second upper pads 221 corresponding to the third chip pads 505. Therefore, the voltage control chip 500 may be electrically connected to the interposer substrate 200 through the conductive bumps 730. The conductive bumps 730 may include conductive solder balls. The conductive solder balls may include a solder material. In some cases, the conductive bumps 730 may further include conductive pillars. In some examples, the conductive pillars may be provided between the third chip pads 505 and the conductive solder balls may include a metal material such as copper.

FIG. 1E is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip.

As shown in FIGS. 1B, 1C, and 1E, a first voltage V1 may be applied to the voltage solder ball terminal 700G from an external device. The first voltage V1 may be applied to the voltage control chip 500 through the third voltage substrate wire 153V and the third voltage interposer wire 253V. The voltage controller 500A of the voltage control chip 500 may convert the first voltage V1 into a second voltage V2. In some cases, the second voltage V2 may be different from the first voltage V1. For example, the second voltage V2 may be smaller than the first voltage V1. The second voltage V2 output from the voltage controller 500A may be transmitted to the inductor 500B. The second voltage V2 may be transmitted to the interposer substrate 200 through the inductor 500B. For example, the second voltage V2 may be transmitted to the first voltage interposer wire 251V and the fourth voltage interposer wire 254V through corresponding conductive bumps 730. A part of the second voltage V2 may be supplied to a first electrode of the first capacitor 271 through the first voltage interposer wire 251V. In some cases, since the first voltage interposer wire 251V is provided, the length of a voltage supply path between the voltage control chip 500 and the first capacitor 271 may be reduced.

A part (e.g., another part) of the second voltage V2 may be supplied to the first capacitor 271 through the second voltage substrate wire 152V. For example, the other part of the second voltage V2 may be transmitted to the second voltage substrate wire 152V through the fourth voltage interposer wire 254V and any one interposer solder ball 630. Thereafter, the other part of the second voltage V2 may be supplied to the first terminal 271A of the first capacitor 271 through the second voltage substrate wire 152V, another interposer solder ball 630, and the first voltage interposer wire 251V.

The second terminal 271B of the first capacitor 271 may be electrically connected to the first semiconductor chip 310 through the fifth voltage interposer wire 255V and a corresponding first bump 710. Therefore, the second voltage V2 output from the second terminal 271B of the first capacitor 271 may be supplied to the first semiconductor chip 310 through the fifth voltage interposer wire 255V.

According to an embodiment, the thickness T1 of the first voltage substrate wire 151V may be greater than the thickness T2 of the first voltage interposer wire 251V. Therefore, the resistance of the first voltage substrate wire 151V may be smaller than the resistance of the first voltage interposer wire 251V. The first voltage substrate wire 151V may exhibit reduced direct current resistance (DCR) characteristics. In some cases, since the other part of the second voltage V2 is supplied to the first semiconductor chip 310 through the first voltage substrate wire 151V, the voltage loss between the voltage control chip 500 and the first semiconductor chip 310 may be prevented, and the voltage drop (IR-Drop) phenomenon may be reduced. Therefore, electrical characteristics such as voltage characteristics of the semiconductor package 10 may be improved. For example, power integrity characteristics between the voltage control chip 500 and the first semiconductor chip 310 may be improved.

The first capacitor 271 may vertically overlap the first semiconductor chip 310. For example, the first capacitor 271 may completely overlap the first semiconductor chip 310 or may partially overlap the first semiconductor chip 310 in the vertical direction. Therefore, the length of a voltage supply path between the first capacitor 271 and the first semiconductor chip 310 may be reduced. The semiconductor package 10 may exhibit further improved voltage characteristics.

As shown in FIGS. 1D and 1E, the first voltage V1 may be applied to the voltage control chip 500 through the voltage solder ball terminal 700G, the third voltage substrate wire 153V, and the third voltage interposer wire 253V. The voltage controller 500A of the voltage control chip 500 may convert the first voltage V1 into the second voltage V2. The second voltage V2 may be transmitted to the interposer substrate 200 through the inductor 500B. For example, a part of the second voltage V2 may be supplied to the first conductive terminal 272A of the second capacitor 272 through the second voltage interposer wire 252V. In some cases, since the second voltage interposer wire 252V is provided, the length of a voltage supply path between the voltage control chip 500 and the second capacitor 272 may be reduced.

A part (e.g., another part) of the second voltage V2 may be supplied to the second capacitor 272 through the second voltage substrate wire 152V. For example, the other part of the second voltage V2 may be transmitted to the second voltage substrate wire 152V through the fourth voltage interposer wire 254V and any one interposer solder ball 630. Thereafter, the second voltage V2 may be supplied to the first conductive terminal 272A of the second capacitor 272 through the second voltage substrate wire 152V, an interposer solder ball 630, and the first voltage interposer wire 251V.

The second conductive terminal 272B of the second capacitor 272 may be electrically connected to the second semiconductor chip 320 through the fifth voltage interposer wire 255V and a corresponding second bump 720. The second voltage V2 output from the second conductive terminal 272B of the second capacitor 272 may be supplied to the second semiconductor chip 320 through the fifth voltage interposer wire 255V.

According to an embodiment, the thickness T10 of the second voltage substrate wire 152V may be greater than the thickness T20 of the second voltage interposer wire 252V. Therefore, the resistance of the second voltage substrate wire 152V may be smaller than the resistance of the second voltage interposer wire 252V. For example, the second voltage substrate wire 152V may exhibit reduced DCR characteristics. Since the other part of the second voltage V2 is supplied to the second semiconductor chip 320 through the second voltage substrate wire 152V, the voltage loss between the voltage control chip 500 and the second semiconductor chip 320 may be prevented, and the IR-Drop phenomenon may be reduced. Therefore, the voltage characteristics of the semiconductor package 10 may be improved. For example, power integrity characteristics between the voltage control chip 500 and the second semiconductor chip 320 may be improved.

As shown in FIG. 1D, the second capacitor 272 may vertically overlap the second semiconductor chip 320. For example, the second capacitor 272 may completely overlap the second semiconductor chip 320 or may partially overlap the second semiconductor chip 320. Therefore, the length of a voltage supply path between the second capacitor 272 and the second semiconductor chip 320 may be reduced. The semiconductor package 10 may exhibit further improved voltage characteristics.

According to an embodiment, as shown in FIGS. 1B and 1D, the first capacitor 271 and the second capacitor 272 may be provided within the interposer substrate 200 and may not be provided on the top surface and the bottom surface of the interposer substrate 200. Therefore, the freedom of arrangement of the interposer solder balls 630, the first bumps 710, and the second bumps 720 may be improved.

According to an embodiment, the second semiconductor chip 320 may be disposed to be adjacent to the first semiconductor chip 310. In some cases, the voltage control chip 500 may not be provided between the first semiconductor chip 310 and the second semiconductor chip 320. In some cases, the first semiconductor chip 310 may be disposed between the second semiconductor chip 320 and the voltage control chip 500. The second semiconductor chip 320 may transmit and receive electrical signals to and from the first semiconductor chip 310 through signal interposer wires 250S. For example, the electrical signals may be data signals. Since the second semiconductor chip 320 may be disposed adjacent to the first semiconductor chip 310, the length of a signal transmission path between the first semiconductor chip 310 and the second semiconductor chip 320 may be reduced. Therefore, the electrical characteristics of the semiconductor package 10 may be improved. For example, semiconductor package 10 may exhibit improved data processing characteristics.

According to an embodiment, a molding layer 400 may be provided on the top surface of the interposer substrate 200 and may cover the first semiconductor chip 310, the second semiconductor chip 320, and the voltage control chip 500. In some cases, sidewalls of the molding layer 400 may be vertically aligned with sidewalls of the interposer substrate 200. The molding layer 400 may include, for example but not limited to, an insulation polymer such as an epoxy-based molding compound (EMC). As used herein, the term ‘vertically aligned’ refers to components or structures that are arranged in a direction perpendicular to a horizontal surface or plane, e.g., oriented along the vertical axis. In some cases, when two components are said to be vertically aligned, the two components may be positioned in a straight line from a top surface to a bottom surface.

A first underfill film 410 may be provided in a first gap area between the interposer substrate 200 and the first semiconductor chip 310 and cover sidewalls of the first bumps 710. A second underfill film 420 may be provided in a second gap area between the interposer substrate 200 and the second semiconductor chip 320 and cover sidewalls of the second bumps 720. A third underfill film 430 may be provided in a third gap area between the interposer substrate 200 and the voltage control chip 500 and cover sidewalls of the conductive bumps 730. According to an example, at least one of the first underfill film 410, the second underfill film 420, and the third underfill film 430 may be omitted. In some examples, the molding layer 400 may further extend into the first gap area, the second gap area, or the third gap area. For example, the first underfill film 410, the second underfill film 420, and the third underfill film 430 may include an epoxy-based insulation polymer. However, embodiments are not limited thereto, and the first underfill film 410, the second underfill film 420, and the third underfill film 430 may include a material different from that constituting the molding layer 400.

Hereinafter, a first voltage substrate wire, a second voltage substrate wire, a first voltage interposer wire, and a second voltage interposer wire are described.

FIG. 1F is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip.

Referring to FIG. 1F together with FIGS. 1B and 1D, the first voltage substrate wire 151V and the second voltage substrate wire 152V may be connected to each other, thereby constituting a voltage transfer substrate wire 150V. According to an embodiment, the voltage transfer substrate wire 150V may include the first voltage substrate wire 151V and the second voltage substrate wire 152V integrated with each other, however, embodiments may not be limited thereto.

A part of the second voltage V2 may be transmitted to the first capacitor 271 through the first voltage interposer wire 251V. In some cases, a part (e.g., another part) of the second voltage V2 may be transmitted to the second capacitor 272 through the second voltage interposer wire 252V. In some cases, a part (e.g., another part) of the second voltage V2 may be transmitted to the first capacitor 271 and the second capacitor 272 through the voltage transfer substrate wire 150V. The second voltage V2 output from the first capacitor 271 may be supplied to the first semiconductor chip 310. The second voltage V2 output from the second capacitor 272 may be supplied to the second semiconductor chip 320.

FIG. 1G is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip.

Referring to FIG. 1G together with FIGS. 1B and 1D, the first voltage interposer wire 251V and the second voltage interposer wire 252V may be connected to each other, thereby constituting a voltage transfer interposer wire 250V. According to an embodiment, the voltage transfer interposer wire 250V may include the first voltage interposer wire 251V and the second voltage interposer wire 252V integrated with each other, however embodiments may not be limited thereto.

A part of the second voltage V2 may be transmitted to the first capacitor 271 and the second capacitor 272 through the voltage transfer interposer wire 250V. In some cases, a part (e.g., another part) of the second voltage V2 may be transmitted to the first capacitor 271 through the first voltage substrate wire 151V. In some cases, a part (e.g., another part) of the second voltage V2 may be transmitted to the second capacitor 272 through the second voltage substrate wire 152V. The second voltage V2 output from the first capacitor 271 may be supplied to the first semiconductor chip 310. The second voltage V2 output from the second capacitor 272 may be supplied to the second semiconductor chip 320.

FIG. 1H is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip.

Referring to FIG. 1H together with FIGS. 1B and 1D, the first voltage substrate wire 151V and the second voltage substrate wire 152V may be connected to each other, thereby constituting the voltage transfer substrate wire 150V. Additionally, the first voltage interposer wire 251V and the second voltage interposer wire 252V may be connected to each other, thereby constituting the voltage transfer interposer wire 250V. The voltage transfer interposer wire 250V may be connected to the voltage transfer substrate wire 150V. The second voltage V2 output from the voltage control chip 500 may be distributed to the voltage transfer substrate wire 150V and the voltage transfer interposer wire 250V.

A part of the second voltage V2 may be supplied to the first capacitor 271 and the second capacitor 272 through the voltage transfer interposer wire 250V. In some cases, a part (e.g., another part) of the second voltage V2 may be supplied to the first capacitor 271 and the second capacitor 272 through the voltage transfer substrate wire 150V. The second voltage V2 output from the first capacitor 271 may be supplied to the first semiconductor chip 310. In some cases, the second voltage V2 output from the second capacitor 272 may be supplied to the second semiconductor chip 320.

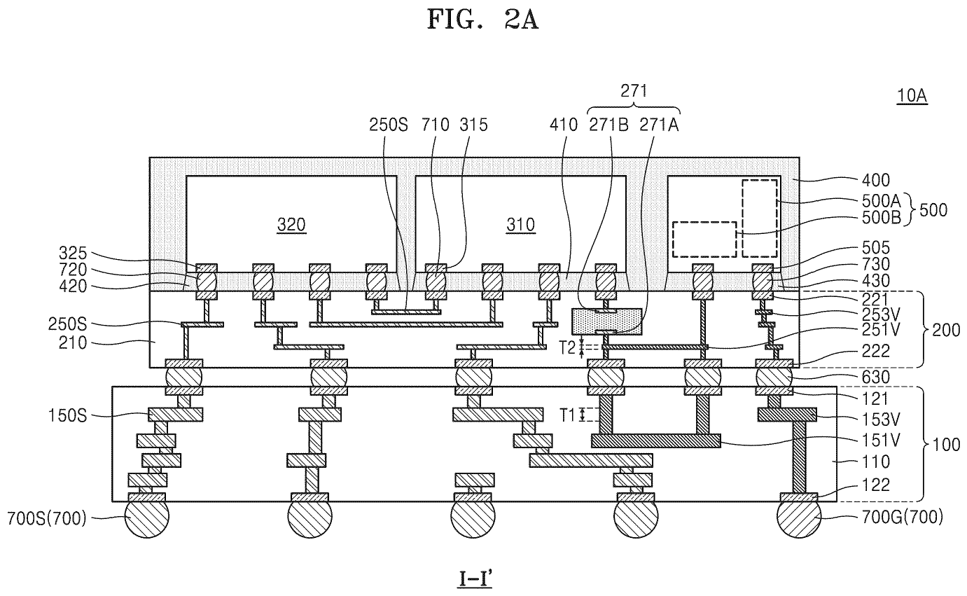

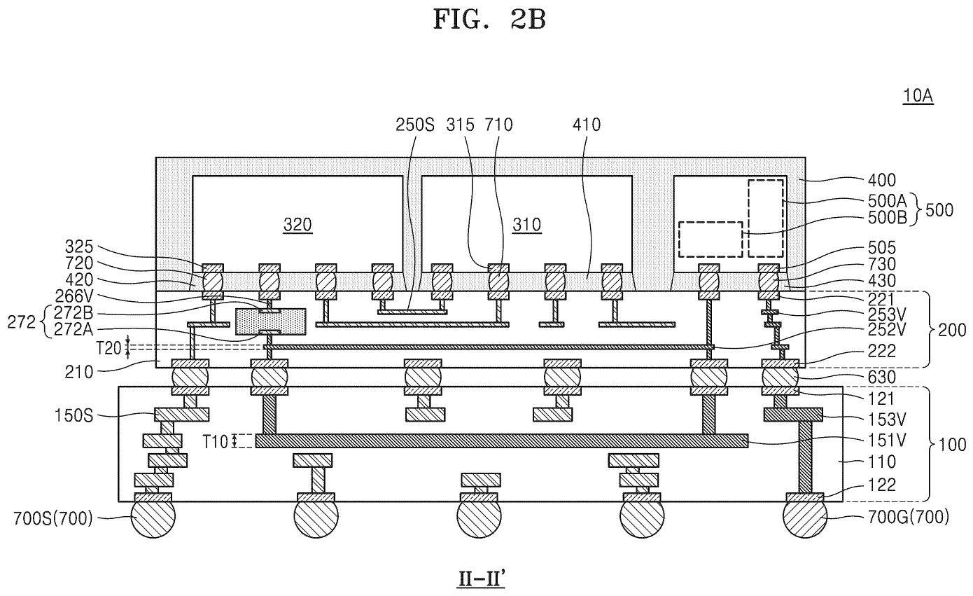

FIG. 2A is a diagram illustrating a semiconductor package according to an embodiment, corresponding to a cross-section taken along a line I-I′ of FIG. 1A. FIG. 2B is a diagram illustrating a semiconductor package according to an embodiment, corresponding to a cross-section taken along a line II-II′ of FIG. 1A. Hereinafter, repeated descriptions will be omitted herein for brevity.

Referring to FIGS. 2A and 2B, a semiconductor package 10A may include the solder ball terminals 700, the package substrate 100, the interposer substrate 200, the first semiconductor chip 310, the second semiconductor chip 320, the voltage control chip 500, and the molding layer 400. The semiconductor package 10A may further include at least one of the interposer solder balls 630, the first bumps 710, the second bumps 720, and the conductive bumps 730.

The interposer substrate 200 may include the second insulation layer 201, the first voltage interposer wire 251V, the second voltage interposer wire 252V, the third voltage interposer wire 253V, the fifth voltage interposer wire 255V, the sixth voltage interposer wire 256V, the signal interposer wires 250S, the first capacitor 271, the second capacitor 272, the second lower pads 222, and the second upper pads 221. In case of FIGS. 2A-2B, the interposer substrate 200 may not include the fourth voltage interposer wire 254V. As shown in FIGS. 2A-2B, the first voltage interposer wire 251V may be electrically connected to the first voltage substrate wire 151V through at least two second lower pads 222 and at least two interposer solder balls 630.

The second voltage V2 output from the voltage control chip 500 may be transmitted to the first voltage interposer wire 251V. A part of the second voltage V2 may be applied to the first terminal 271A of the first capacitor 271 through the first voltage interposer wire 251V. In some cases, a part (e.g., another part) of the second voltage V2 may be transmitted to the first voltage interposer wire 251V and then applied to the first terminal 271A of the first capacitor 271 through the first voltage substrate wire 151V.

As shown in FIG. 2B, the second voltage interposer wire 252V may be electrically connected to the second voltage substrate wire 152V through at least two second lower pads 222 and at least two interposer solder balls 630.

A part of the second voltage V2 output from the voltage control chip 500 may be applied to the first conductive terminal 272A of the second capacitor 272 through the second voltage interposer wire 252V. In some cases, a part (e.g., another part) of the second voltage V2 may be transmitted to the second voltage interposer wire 252V and then applied to the first conductive terminal 272A of the second capacitor 272 through the second voltage substrate wire 152V.

According to an embodiment, the second voltage interposer wire 252V may be connected to the first voltage interposer wire 251V. In some cases, the second voltage interposer wire 252V may be spaced apart from the first voltage interposer wire 251V without being connected thereto.

According to an embodiment, the second voltage substrate wire 152V may be connected to the first voltage substrate wire 151V. In some cases, the second voltage substrate wire 152V may be spaced apart from the first voltage substrate wire 151V without being connected thereto.

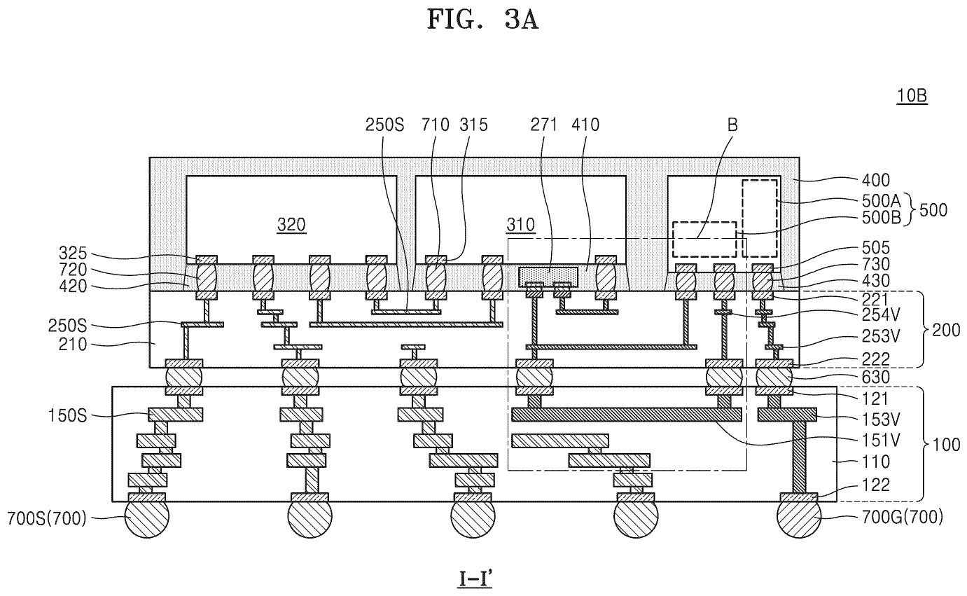

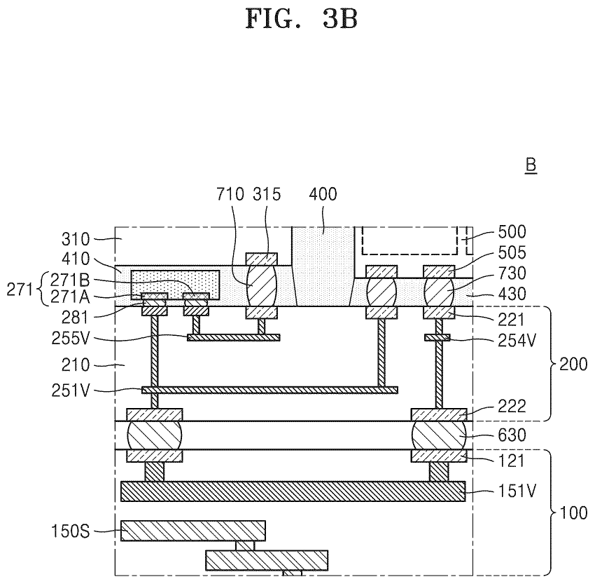

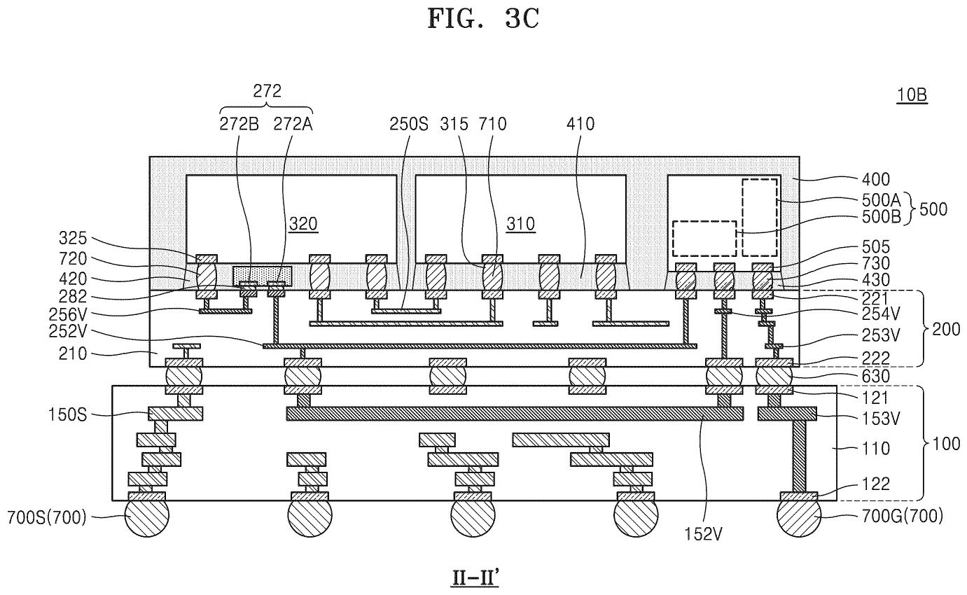

FIG. 3A is a diagram illustrating a semiconductor package according to an embodiment, corresponding to a cross-section taken along a line I-I′ of FIG. 1A. FIG. 3B is an enlarged view of a region B of FIG. 3A. FIG. 3C is a diagram illustrating a semiconductor package according to an embodiment, corresponding to a cross-section taken along a line II-II′ of FIG. 1A. Hereinafter, repeated descriptions are omitted herein for brevity.

Referring to FIGS. 3A to 3C, a semiconductor package 10B may include the solder ball terminals 700, the package substrate 100, the interposer substrate 200, the first semiconductor chip 310, the second semiconductor chip 320, the voltage control chip 500, and the molding layer 400.

The interposer substrate 200 may be substantially identical to the interposer substrate described with reference to FIGS. 1A to 1H or FIGS. 2A and 2B. The interposer substrate 200 may include the second insulation layer 201, the first to sixth voltage interposer wires 251V, 252V, 253V, 254V, 255V, and 256V, the signal interposer wires 250S, the first capacitor 271, the second capacitor 272, the second lower pads 222, and the second upper pads 221.

However, the first capacitor 271 may be disposed on the top surface of the interposer substrate 200. For example, the first capacitor 271 may be disposed between the top surface of the interposer substrate 200 and the bottom surface of the first semiconductor chip 310. For example, the first capacitor 271 may be disposed to be laterally spaced apart from the first bumps 710. As shown in FIG. 3B, the first voltage interposer wire 251V may be electrically connected to the first terminal 271A of the first capacitor 271. The second terminal 271B of the first capacitor 271 may be electrically connected to the first semiconductor chip 310 through the fifth voltage interposer wire 255V and a corresponding first bump 710.

First connection solders 281 may be provided between the interposer substrate 200 and the first capacitor 271. Any one of the first connection solders 281 may be connected to the first voltage interposer wire 251V and the first terminal 271A of the first capacitor 271. In some cases, another one of the first connection solders 281 may be connected to the second terminal 271B of the first capacitor 271 and the fifth voltage interposer wire 255V. The first connection solders 281 may include a solder material. The first connection solders 281 may be spaced apart and may be electrically isolated from each other.

As shown in FIG. 3C, the second capacitor 272 may be disposed on the top surface of the interposer substrate 200. For example, the second capacitor 272 may be disposed between the top surface of the interposer substrate 200 and the bottom surface of the second semiconductor chip 320. According to an embodiment, the second capacitor 272 may be disposed to be laterally spaced apart from the second bumps 720. The second voltage interposer wire 252V may be electrically connected to the first conductive terminal 272A of the second capacitor 272. The second conductive terminal 272B of the second capacitor 272 may be electrically connected to the second semiconductor chip 320 through the sixth voltage interposer wire 256V and the corresponding second bump 720.

Second connection solders 282 may be provided between the interposer substrate 200 and the second capacitor 272. Any one of the second connection solders 282 may be connected to the second voltage interposer wire 252V and the first conductive terminal 272A of the second capacitor 272. In some cases, another one of the second connection solders 282 may be connected to the second conductive terminal 272B of the second capacitor 272 and the fifth voltage interposer wire 255V. The second connection solders 282 may include a solder material. The second connection solders 282 may be spaced apart and may be electrically isolated from each other.

According to an embodiment, since the first capacitor 271 and the second capacitor 272 are disposed on the top surface of the interposer substrate 200, the difficulty of the process for manufacturing the interposer substrate 200 may be reduced.

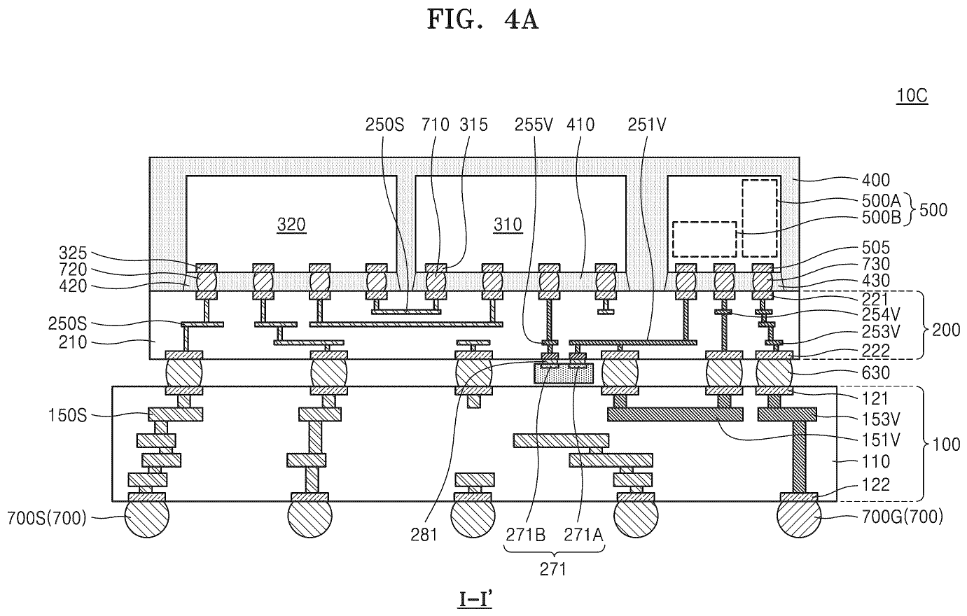

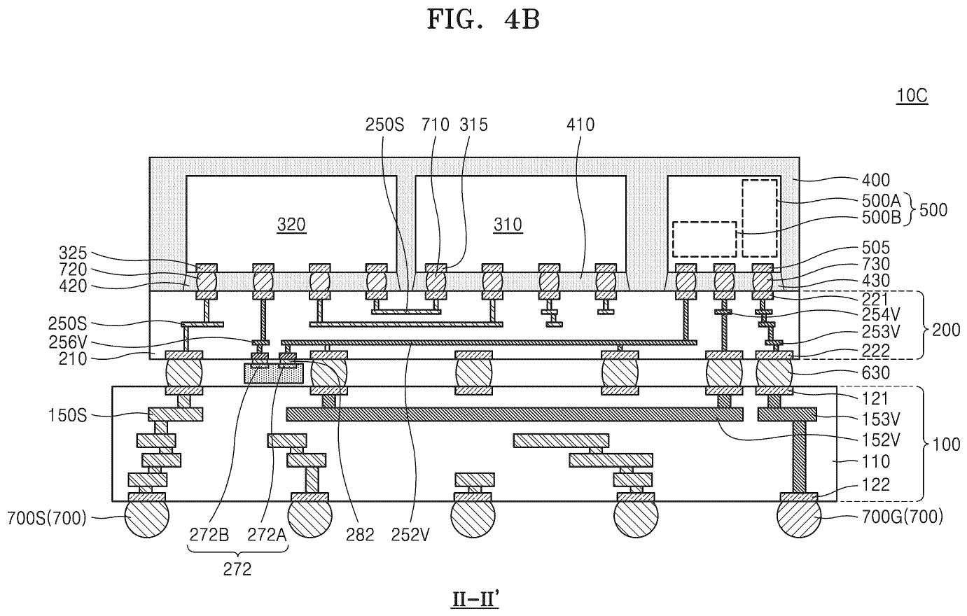

FIG. 4A is a diagram illustrating a semiconductor package according to an embodiment, corresponding to a cross-section taken along a line I-I′ of FIG. 1A. FIG. 4B is a diagram illustrating a semiconductor package according to an embodiment, corresponding to a cross-section taken along a line II-II′ of FIG. 1A. Hereinafter, repeated descriptions are omitted herein for brevity.

Referring to FIGS. 4A and 4B, a semiconductor package 10C may include the solder ball terminals 700, the package substrate 100, the interposer substrate 200, the first semiconductor chip 310, the second semiconductor chip 320, the voltage control chip 500, and the molding layer 400.

The interposer substrate 200 may include the second insulation layer 201, the first to sixth voltage interposer wires 251V, 252V, 253V, 254V, 255V, and 256V, the signal interposer wires 250S, the first capacitor 271, the second capacitor 272, the second lower pads 222, and the second upper pads 221. As shown in FIG. 4A, the first capacitor 271 may be disposed on the bottom surface of the interposer substrate 200. For example, the first capacitor 271 may be disposed between the bottom surface of the interposer substrate 200 and the top surface of the package substrate 100. In some examples, the first capacitor 271 may be disposed to overlap the first semiconductor chip 310. The first capacitor 271 may be disposed to be laterally spaced apart from the interposer solder balls 630. The first connection solders 281 may be provided between the interposer substrate 200 and the first capacitor 271. The first voltage interposer wire 251V may be electrically connected to the first terminal 271A of the first capacitor 271. The second terminal 271B of the first capacitor 271 may be electrically connected to the first semiconductor chip 310 through the fifth voltage interposer wire 255V and a corresponding first bump 710.

As shown in FIG. 4B, the second capacitor 272 may be disposed on the bottom surface of the interposer substrate 200. For example, the second capacitor 272 may be disposed between the bottom surface of the interposer substrate 200 and the top surface of the package substrate 100. In some examples, the second capacitor 272 may be disposed to overlap the second semiconductor chip 320. The second capacitor 272 may be disposed to be laterally spaced apart from the interposer solder balls 630. The second connection solders 282 may be provided between the interposer substrate 200 and the second capacitor 272. The second voltage interposer wire 252V may be electrically connected to the first conductive terminal 272A of the second capacitor 272. The second conductive terminal 272B of the second capacitor 272 may be electrically connected to the second semiconductor chip 320 through the sixth voltage interposer wire 256V and the corresponding second bump 720.

According to an embodiment, since the first capacitor 271 and the second capacitor 272 are disposed on the bottom surface of the interposer substrate 200, the difficulty of the process for manufacturing the interposer substrate 200 may be reduced.

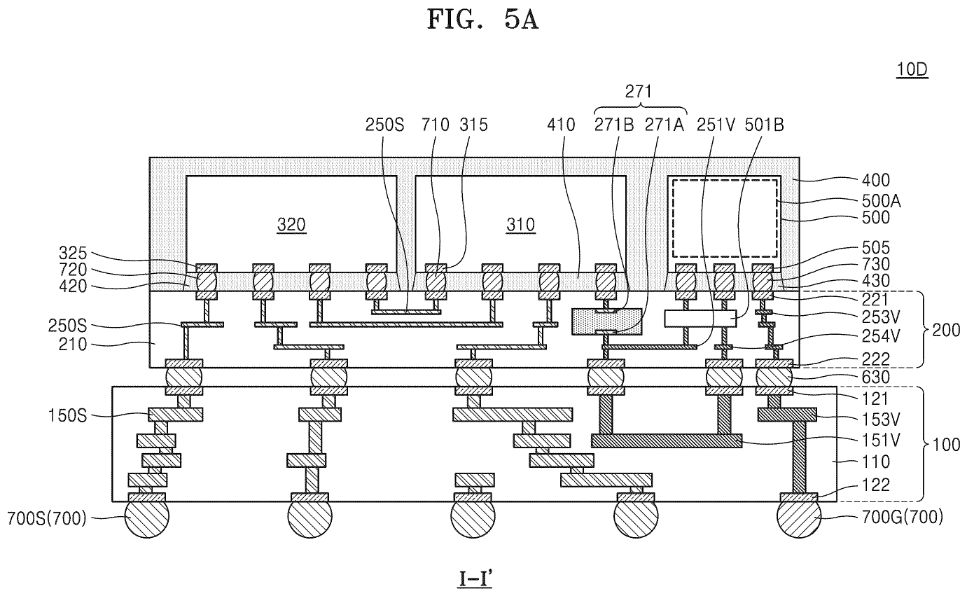

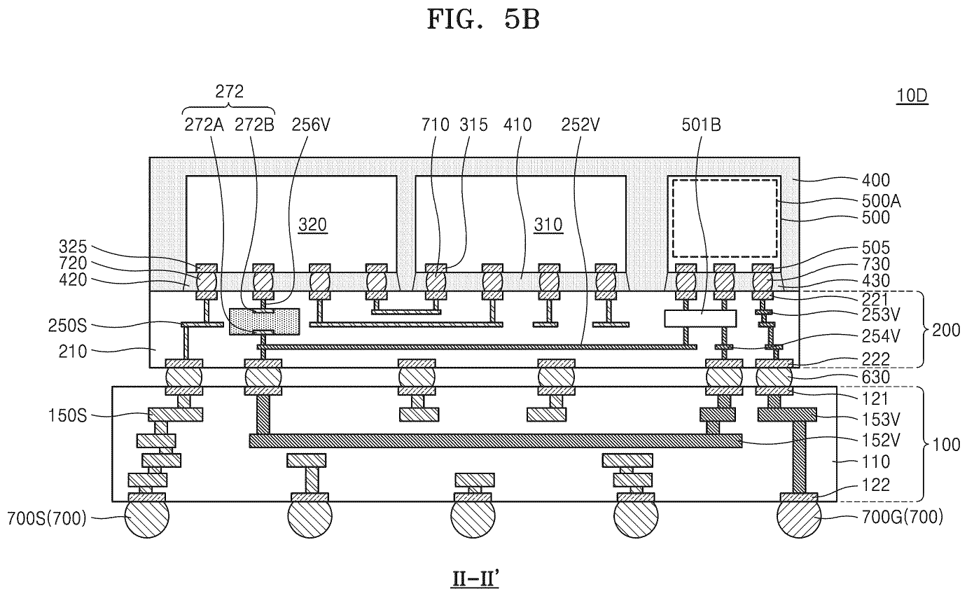

FIG. 5A is a diagram illustrating a semiconductor package according to an embodiment, corresponding to a cross-section along a line I-I′ of FIG. 1A. FIG. 5B is a diagram illustrating a semiconductor package according to an embodiment, corresponding to a cross-section along a line II-IT′ of FIG. 1A. Hereinafter, repeated descriptions are omitted herein for brevity.

Referring to FIGS. 5A and 5B, a semiconductor package 10D may include the solder ball terminals 700, the package substrate 100, the interposer substrate 200, the first semiconductor chip 310, the second semiconductor chip 320, the voltage control chip 500, and the molding layer 400. Additionally, the semiconductor package 10D may further include an inductor element 501B. In some examples, the voltage control chip 500 may include the voltage controller 500A, but may not include the inductor (inductor 500B described with reference to FIGS. 1B and 1D).

The inductor element 501B may be provided within the interposer substrate 200. For example, the inductor element 501B may be provided between first and second voltage interposer wires 251V and 252V and second upper pads 221 corresponding to the first and second voltage interposer wires 251V and 252V. When the interposer substrate 200 further includes the fourth voltage interposer wire 254V, the inductor element 501B may extend between the fourth voltage interposer wire 254V and at least one second upper pad 221 corresponding to the fourth voltage interposer wire 254V.

The second voltage V2 output from the voltage control chip 500 may be transmitted to the inductor element 501B through the conductive bumps 730. The second voltage V2 may be transmitted to the first voltage interposer wire 251V and the second voltage interposer wire 252V through the inductor element 501B. When the interposer substrate 200 includes the fourth voltage interposer wire 254V, the second voltage V2 may be further transmitted to the fourth voltage interposer wire 254V through the inductor element 501B.

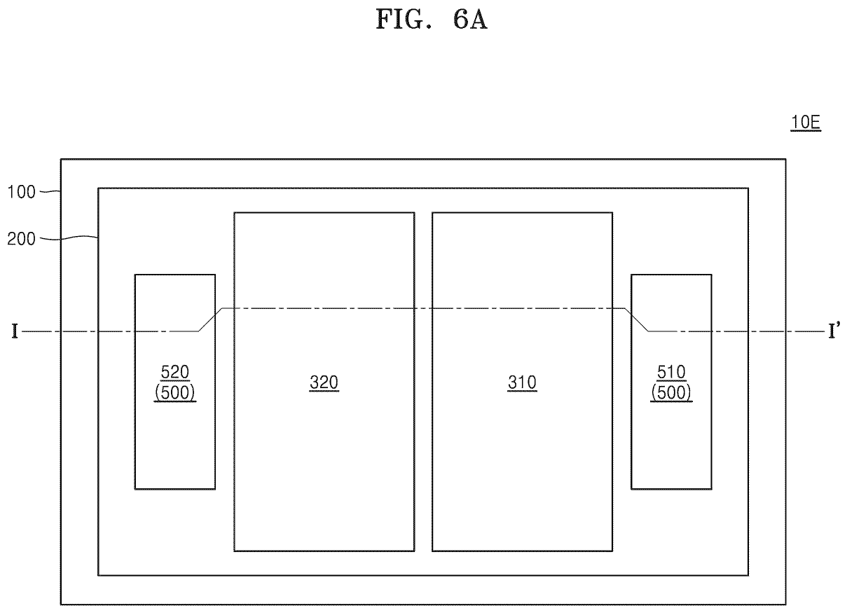

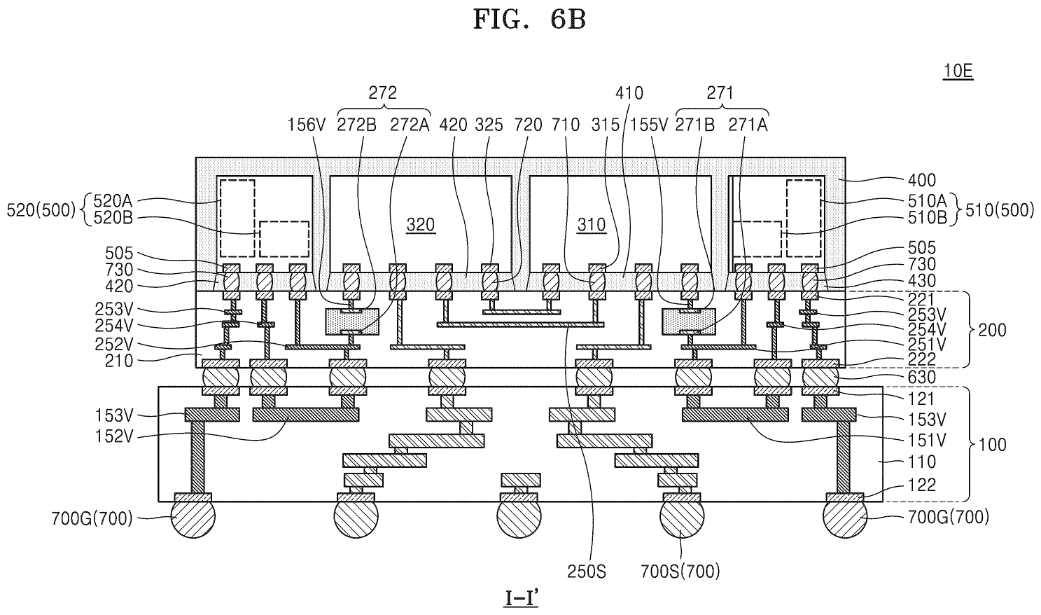

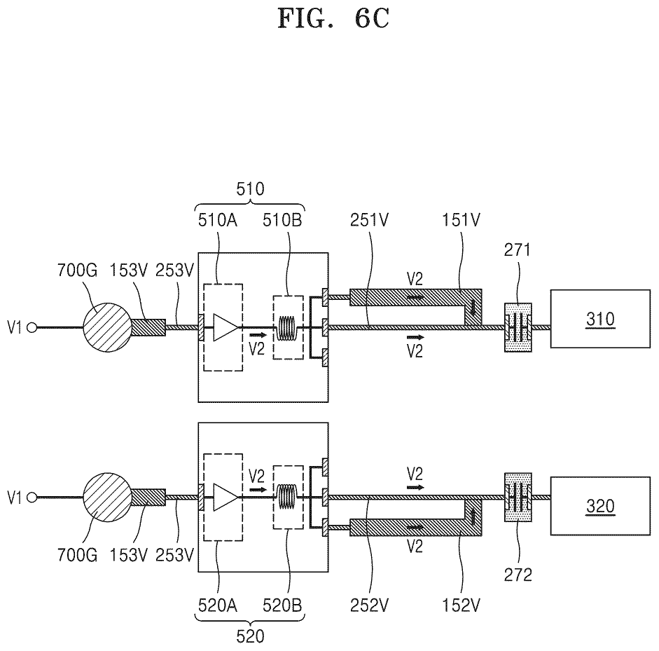

FIG. 6A is a plan view of a semiconductor package according to an embodiment. FIG. 6B is a cross-sectional view of the semiconductor package of FIG. 6A, taken along a line I-I′. FIG. 6C is a schematic diagram illustrating electrical connections between a voltage solder ball terminal, a voltage control chip, a first voltage substrate wire, a second voltage substrate wire, a first voltage interposer wire, a second voltage interposer wire, a first capacitor, a second capacitor, a first semiconductor chip, and a second semiconductor chip of the semiconductor package of FIG. 6A.

Referring to FIGS. 6A to 6C, a semiconductor package 10E may include the solder ball terminals 700, the package substrate 100, the interposer substrate 200, the first semiconductor chip 310, the second semiconductor chip 320, the voltage control chip 500, and the molding layer 400.

The voltage control chip 500 may include a first voltage control chip 510 and a second voltage control chip 520. The second voltage control chip 520 may be laterally spaced apart from the first semiconductor chip 310, the second semiconductor chip 320, and the first voltage control chip 510. In some cases, the first semiconductor chip 310 and the second semiconductor chip 320 may be arranged between the first voltage control chip 510 and the second voltage control chip 520. As shown in FIG. 6B, the first voltage control chip 510 may be disposed adjacent to the first semiconductor chip 310. The first voltage control chip 510 may be disposed between the first semiconductor chip 310 and a second side of the interposer substrate 200. The first voltage control chip 510 may include a first voltage controller 510A and a first inductor 510B. The first voltage controller 510A and the first inductor 510B may be substantially identical to the voltage controller 500A and the inductor 500B described with reference to FIGS. 1B and 1E, respectively.

The solder ball terminals 700 may include a plurality of voltage solder ball terminals 700G. The package substrate 100 may include a plurality of third voltage substrate wires 153V. The interposer substrate 200 may include a plurality of third voltage interposer wires 253V and a plurality of fourth voltage interposer wires 254V.

In some cases, the first voltage V1 may be applied to the voltage solder ball terminals 700G from an external device. The first voltage V1 may be applied from any one of the voltage solder ball terminals 700G to the first voltage control chip 510 through any one of the third voltage substrate wires 153V and any one of the third voltage interposer wires 253V. The first voltage controller 510A may convert the first voltage V1 into the second voltage V2. The second voltage V2 converted by the first voltage controller 510A may be output through the first inductor 510B.

In some cases, the second voltage V2 output from the first voltage control chip 510 may be supplied to the first terminal 271A of the first capacitor 271 through the first voltage interposer wire 251V. Additionally, the second voltage V2 output from the first voltage control chip 510 may be transmitted to the first voltage substrate wire 151V through any one of the fourth voltage interposer wires 254V. The second voltage V2 may be supplied to the first terminal 271A of the first capacitor 271 through the first voltage substrate wire 151V. The second voltage V2 output from the second terminal 271B of the first capacitor 271 may be supplied to the first semiconductor chip 310.

The second voltage control chip 520 may be disposed adjacent to the second semiconductor chip 320. The second voltage control chip 520 may be disposed between the second semiconductor chip 320 and a first side of the interposer substrate 200. The second voltage control chip 520 may include a second voltage controller 520A and a second inductor 520B. The second voltage controller 520A and the second inductor 520B may be substantially identical to the voltage controller 500A and the inductor 500B described with reference to FIGS. 1B and 1E, respectively.

In some cases, the first voltage V1 may be applied from another one of the voltage solder ball terminals 700G to the second voltage control chip 520 through another one of the third voltage substrate wires 153V and another one of the third voltage interposer wires 253V. The second voltage controller 520A may convert the first voltage V1 into the second voltage V2. The second voltage V2 converted by the second voltage controller 520A may be output through the second inductor 520B. The second voltage V2 output from the second voltage control chip 520 may be supplied to the first conductive terminal 272A of the second capacitor 272 through the second voltage interposer wire 252V. Additionally, the second voltage V2 output from the second voltage control chip 520 may be transmitted to the second voltage substrate wire 152V through another one of the fourth voltage interposer wires 254V. The second voltage V2 may be supplied to the first conductive terminal 272A of the second capacitor 272 through the second voltage substrate wire 152V. The second voltage V2 output from the second conductive terminal 272B of the second capacitor 272 may be supplied to the second semiconductor chip 320.

One or more embodiments of the present disclosure may be combined with each other. As an example, at least two embodiments from among the embodiment of FIGS. 1A to 1D, the embodiment of FIG. 1E, the embodiment of FIG. 1F, the embodiment of FIG. 1G, the embodiment of FIG. 1H, the embodiment of FIGS. 2A and 2B, the embodiment of FIGS to 3C, the embodiment of FIGS. 4A and 4B, the embodiment of FIGS. 5A and 5B, and the embodiment of FIGS. 6A to 6C may be combined with each other. For example, the semiconductor package 10A of FIGS. 2A and 2B, the semiconductor package 10B of FIGS. 3A to 3C, the semiconductor package 10C of FIGS. 4A and 4B, and the second voltage substrate wire of the semiconductor package 10D of FIGS. 5A and 5B may be connected to the first voltage substrate wire as shown with reference to FIGS. 1F and 1H, thereby forming a voltage transfer substrate wire. In some cases, the combination of embodiments may be modified in various ways.

According to an embodiment, a voltage output from a voltage control chip may be supplied to a semiconductor chip through a voltage interposer wire and a voltage substrate wire. The thickness of the voltage substrate wire may be greater than the thickness of the voltage interposer wire. Additionally, the resistance of the voltage substrate wire may be less than the resistance of the voltage interposer wire. Therefore, voltage loss may be prevented during a voltage supply process and a voltage drop phenomenon may be reduced. The power integrity characteristics between a voltage control chip and a first semiconductor chip may be improved. Accordingly, the semiconductor package may exhibit improved electrical properties.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate comprising a first voltage substrate wire;
an interposer substrate disposed on the package substrate and comprising a first voltage interposer wire;
a first semiconductor chip mounted on a top surface of the interposer substrate; and
a voltage control chip disposed on the top surface of the interposer substrate and laterally spaced apart from the first semiconductor chip,
wherein the first semiconductor chip is electrically connected to the voltage control chip through the first voltage substrate wire, and wherein the first semiconductor chip is electrically connected to the voltage control chip through the first voltage interposer wire.

2. The semiconductor package of claim 1, wherein a thickness of the first voltage substrate wire is greater than a thickness of the first voltage interposer wire.

3. The semiconductor package of claim 1, wherein the interposer substrate further comprises a first capacitor vertically overlapping the first semiconductor chip, and
the first capacitor comprises:
a first terminal electrically connected to the first voltage interposer wire; and
a second terminal electrically connected to the first semiconductor chip.

4. The semiconductor package of claim 3, wherein the first capacitor is located within the interposer substrate.

5. The semiconductor package of claim 3, wherein the first capacitor is disposed on the top surface or a bottom surface of the interposer substrate.

6. The semiconductor package of claim 1, further comprising a second semiconductor chip mounted on the top surface of the interposer substrate and laterally spaced apart from the first semiconductor chip and the voltage control chip,
wherein the package substrate further comprises a second voltage substrate wire,
the interposer substrate further comprises a second voltage interposer wire, and
the second semiconductor chip is electrically connected to the voltage control chip through the second voltage substrate wire and the second voltage interposer wire.

7. The semiconductor package of claim 6, wherein a thickness of the second voltage substrate wire is greater than a thickness of the first voltage interposer wire.

8. The semiconductor package of claim 6, wherein the second voltage substrate wire is connected to the first voltage substrate wire, and
the second voltage interposer wire is connected to the first voltage interposer wire.

9. The semiconductor package of claim 6, wherein the interposer substrate further comprises a second capacitor vertically overlapping the second semiconductor chip,
the second capacitor is disposed within the interposer substrate, and
the second capacitor comprises:
a first conductive terminal electrically connected to the second voltage interposer wire; and
a second conductive terminal electrically connected to the second semiconductor chip.

10. The semiconductor package of claim 1, wherein the voltage control chip comprises:
a voltage controller configured to convert a first voltage into a second voltage; and
an inductor connected to the voltage controller and configured to receive the second voltage, and
the second voltage is less than the first voltage.

11. A semiconductor package comprising:
a package substrate comprising a first voltage substrate wire;
an interposer substrate disposed on the package substrate and comprising a first voltage interposer wire and a first capacitor;
a first semiconductor chip mounted on a top surface of the interposer substrate; and
a first voltage control chip disposed on the top surface of the interposer substrate and laterally spaced apart from the first semiconductor chip,
wherein the first capacitor comprises:
a first terminal connected to the first semiconductor chip; and
a second terminal electrically connected to the first voltage substrate wire, and
wherein a thickness of the first voltage substrate wire is greater than a thickness of the first voltage interposer wire.

12. The semiconductor package of claim 11, wherein the first terminal of the first capacitor is further electrically connected to the first voltage interposer wire.

13. The semiconductor package of claim 11, wherein the thickness of the first voltage substrate wire is between 5 μm and 50 μm, and
the thickness of the first voltage interposer wire is between 1 μm and 10 μm.

14. The semiconductor package of claim 11, further comprising: a second semiconductor chip disposed on the top surface of the interposer substrate; and
a second voltage control chip disposed on the top surface of the interposer substrate and laterally spaced apart from the first semiconductor chip, the second semiconductor chip, and the first voltage control chip,
wherein the package substrate further comprises a second voltage substrate wire,
the interposer substrate further comprises a second voltage interposer wire, and
the second semiconductor chip is electrically connected to the second voltage control chip through the second voltage substrate wire, and wherein the second semiconductor chip is electrically connected to the voltage control chip through the second voltage interposer wire.

15. The semiconductor package of claim 14, wherein the first semiconductor chip and the second semiconductor chip are disposed between the first voltage control chip and the second voltage control chip.

16. A semiconductor package comprising:
a package substrate comprising a first voltage substrate wire, a voltage supply substrate wire, and a signal wire;
solder ball terminals disposed on a bottom surface of the package substrate;
an interposer substrate disposed on a top surface of the package substrate and comprising a first voltage interposer wire, a voltage supply interposer wire, a signal interposer wire, and a first capacitor;
interposer solder balls disposed between the package substrate and the interposer substrate;
a first semiconductor chip disposed on a top surface of the interposer substrate;
first bumps disposed between the interposer substrate and the first semiconductor chip and connected to the interposer substrate and the first semiconductor chip;
a voltage control chip disposed on the top surface of the interposer substrate and laterally spaced apart from the first semiconductor chip; and
a molding layer disposed on the top surface of the interposer substrate and covering the first semiconductor chip and the voltage control chip,
wherein the first capacitor comprises:
a first terminal connected to the first voltage substrate wire and the first voltage interposer wire; and
a second terminal electrically connected to the first semiconductor chip,
wherein the solder ball terminals comprise a voltage solder ball terminal and a signal solder ball terminal,
the voltage solder ball terminal is electrically connected to the first voltage control chip through the voltage supply substrate wire and the voltage supply interposer wire,
the first voltage substrate wire is insulated from the voltage supply substrate wire,
the first voltage interposer wire is insulated from the voltage supply interposer wire, and
a thickness of the first voltage substrate wire is greater than a thickness of the first voltage interposer wire.

17. The semiconductor package of claim 16, wherein the voltage control chip is electrically connected to the first voltage interposer wire and the first voltage substrate wire.

18. The semiconductor package of claim 16, further comprising a second semiconductor chip disposed on the top surface of the interposer substrate and laterally spaced apart from the first semiconductor chip and the voltage control chip,
wherein the package substrate further comprises a second voltage substrate wire,
the interposer substrate further comprises a second voltage interposer wire and a second capacitor,
the second capacitor comprises:
a first conductive terminal connected to the second voltage substrate wire and the second voltage interposer wire; and
a second conductive terminal electrically connected to the second semiconductor chip,
wherein the second voltage substrate wire is insulated from the voltage supply substrate wire,
the second voltage interposer wire is insulated from the voltage supply interposer wire, and
a thickness of the second voltage substrate wire is greater than a thickness of the second voltage interposer wire.

19. The semiconductor package of claim 18, wherein the second voltage interposer wire and the second voltage substrate wire are electrically connected to the voltage control chip.

20. The semiconductor package of claim 18, wherein the second semiconductor chip is electrically connected to the first semiconductor chip through the signal interposer wire, and
the first semiconductor chip is disposed between the second semiconductor chip and the voltage control chip.
